(19) United States
(12) Patent Application Publication
(10) Pub. No.: US 2021/0389391 A1
(43) Pub. Date: Dec. 16, 2021

(54) System and Method for Reservoir Monitoring Using SQUID Magnetic Sensors

(71) Applicants: TechnoImaging, LLC, Salt Lake City, UT (US); Japan Oil, Gas and Metals National Corporation, Tokyo (JP)

(72) Inventors: Michael S. Zhdanov, Holladay, UT (US); Leif H. Cox, Butte, MT (US); Alex Gribenko, Salt Lake City, UT (US); Hideaki Ban, Tokyo (JP); Hiroshi Chiba, Zushi City (JP)

(21) Appl. No.: 17/183,094

(22) Filed: Feb. 23, 2021

Related U.S. Application Data
(60) Provisional application No. 63/038,007, filed on Jun. 11, 2020.

(51) Int. Cl. G01R 33/035; G01V 3/12; G01V 3/26

(52) U.S. Cl. CPC G01R 33/0354; G01V 3/26; G01V 3/12

(57) ABSTRACT

A vertical bipole source in a borehole generates a vertical bipole flow. The vertical bipole flow generates mutually orthogonal time-domain B-field data. Magnetic receivers at a surface location receive the time-domain B-field data and determine elements of a hydrocarbon reservoir using a 3D EM inversion technique. The vertical bipole source may extend into the borehole or be a virtual bipole source located at a surface location above a reservoir.

### CROSS-REFERENCE TO RELATED APPLICATIONS/PUBLICATIONS

This application is related to and claims the benefit of U.S. Provisional Patent Application 63/038,007, filed Jun. 11, 2020, the entirety of which is incorporated herein by reference.

### BACKGROUND OF THE INVENTION

### 1. The Field of the Invention

The present disclosure relates in general to reservoir imaging and monitoring using surface and borehole geophysical data.

### 2. The Background

Monitoring and control the behavior of the hydrocarbon (HC) reservoir over the course of production, or carbon dioxide (CO2) injections in a deep reservoir in carbon capture and storage (CCS) projects, or geothermal field study, represent an important technique in optimization of reservoir performance and production strategies. Until recently, the main methods used in solving this problem were based on seismic field measurements. The use of seismic data for monitoring, however, is very challenging because of the small variation of seismic velocities over time and because of the difficulty of survey repeatability.

Over the last decades, there was increased interest in using electromagnetic (EM) methods for reservoir monitoring, which could be used as complementary to the seismic method, and in many cases manifest a higher sensitivity to the movement of the fluids in the reservoir than the seismic data (e.g. as described by Strack in U.S. Pat. No. 6,739,165; by Constable in U.S. Pat. No. 7,109,717; by Hendrix in U.S. Pat. No. 9,983,328).

Stolie and Dvergsten (EP 1,803,001 B 1) introduced method of resistivity mapping hydrocarbon (HC) reservoir based on injection of tracer fluid, which has resistivity different from the resistivity of the formation. However, the use of this method is limited by the fact that the injected fluid used in drilling process is very conductive by itself and adding conductive particles may provide insignificant effect on the observed EM data.

The main difficulty in application of the EM methods for reservoir monitoring is related to the fact that the response from the deep reservoir is typically very weak, which makes it difficult to detect this response and to obtain meaningful information about the movement of the fluid in the reservoir by using the conventional magnetic and/or electric sensors located on the ground.

This application hereby incorporates the following publications by reference in their entirety: Zhdanov, M. S., 2015, Inverse theory and applications in geophysics: Elsevier; Zhdanov, M. S., 2018, Foundations of geophysical electromagnetic theory and methods: Elsevier. Other references cited: U.S. Pat. No. 6,739,165, Strack; EP 1,803,001 B1, Stolie and Dvergsten; U.S. Pat. No. 7,109,717, Constable; U.S. Pat. No. 9,983,328, Hendrix.

Devices, systems, and methods of the present disclosure may use a specific transmitter-receiver configurations, which can generate an enhanced response from the reservoirs filled with fluids (e.g., water, oil and gas).

Devices, systems, and methods of the present disclosure may increase the depth of investigation with the surface EM survey by measuring the magnetic B field, instead of its time derivative, dB/dt, which ensures the recording EM response at later time corresponding to greater depth than by using the conventional induction coils magnetic sensors or electric field sensors. This goal can be achieved by using superconducting quantum interference device (SQUID) sensors to measure extremely small changes in magnetic fields generated by the movement of the fluid in the reservoir rocks.

### BRIEF SUMMARY

At least one embodiment of a method disclosed herein, for example, can be applied for subsurface reservoir monitoring, using SQUID sensors to measure the time decay of the magnetic field generated in the subsurface reservoir by an electric source, located in the borehole or on the ground, and acquired from a set of SQUID receivers located on the surface in the area above the deep reservoir or in the borehole.

An embodiment of the method disclosed herein may be used for monitoring of the movement of fluids in the hydrocarbon bearing reservoir.

Another embodiment of the method of the present invention may be used for monitoring carbon dioxide (CO2) injections in a deep reservoir in carbon capture and storage (CCS) projects.

In carbonate reservoirs, for example, the host rocks themselves may be relatively resistive, meaning there is a weaker resistivity contrast between the hydrocarbon-bearing reservoir and its hosts. The presence of low salinity aquifers further reduces this resistivity contrast, and thus limits the applicability of conventional induction coils magnetic or electric receivers.

Another embodiment of the method of the present invention may be used for monitoring geothermal resources.

Experimental study shows that creating a vertical flow of current will couple better with the deeply seated resistive reservoir than the currently used horizontal electric bipole source, located on the ground.

At least one embodiment of this method may be based on injection a pulse of the current in the borehole by a vertical long (several hundred meters up to a few kms) bipole source physically installed in the borehole. The volume of the reservoir rocks penetrated by the injected current may be characterized by significant anomalies in the distribution of the magnetic field measured by the ground or borehole-based array of magnetic SQUID sensors at different time moments after the electric source pulse.

At yet another embodiment of this invention, the current electrodes may be placed on the ground in such a manner which simulates the vertical bipole (e.g., a cross, star, circular, or square electrode configurations on the ground). The time-domain magnetic response of the reservoir is measured by a set of SQUID magnetic field receivers located on the ground in the area over the reservoir, and/or in the borehole(s) passing close or intersecting the reservoir.

At least one embodiment of a method disclosed herein may be used for determining the distribution of electromagnetic properties within the reservoir layers from the recorded time-domain magnetic field data. This distribution is used to monitor the movement of the injected fluid within the reservoir.

Broadly, the disclosure describes a method for subsurface reservoir monitoring, using the injection of electric pulse current by the actual or virtual vertical electric bipole source which produces a strong magnetic field anomaly due to presence of a fluid in the reservoir rocks. The method may include a) placing at least one actual vertical electric bipole source in the borehole or a system of horizontal electric bipoles on the ground, which will simulate a virtual vertical electric bipole; b) placing at least one magnetic field receiver or an array of receivers on the ground over the reservoir; c) placing at least one magnetic field receiver or an array of receivers in at least one borehole passing close or intersecting the reservoir. The anomalous time-domain magnetic field data produced by the reservoir layers penetrated by the injected vertical electric current may be recorded by the at least one receiver along the survey lines or over a survey area. The recorded data measured at the at least one receiver or over a survey area may be used to produce a numerical reconstruction of the electromagnetic properties in the reservoir layers, providing monitoring of the movement of the fluid in the subsurface geological formations.

### BRIEF DESCRIPTION OF THE DRAWINGS

Exemplary embodiments of the invention will become more fully apparent from the following description and appended claims, taken in conjunction with the accompanying drawings. Understanding that these drawings depict only exemplary embodiments and are, therefore, not to be considered limiting of the invention's scope, the exemplary embodiments of the invention will be described with additional specificity and detail through use of the accompanying drawings in which:

FIG. 1 illustrates an embodiment of a reservoir monitoring system for measuring the magnetic B(t) field response from the reservoir rocks, using an actual vertical electric current source. The system is formed by a transmitting vertical electric bipole consisting of two electrode points: one surface grounding point, the electrode 1, and electrode 2 grounded at well casing or inside the borehole, and a set of magnetic field receivers 3, distributed around the borehole. Borehole 4 with or without metal casing may penetrate the target reservoir 5.

FIG. 2 illustrates an embodiment of the present invention of the surface electrode configuration of a reservoir monitoring system, simulating a virtual vertical electric bipole source. The figure shows four possible surface electrode configurations: (6) cross electrodes; (7) star electrodes; (8) circle electrodes; and (9) square electrodes. For all configurations, the surface grounding points (10) represent transmitting electrodes, and the surface grounding point (11) represents a receiving electrode.

FIG. 3 illustrates an embodiment of a reservoir monitoring system for measuring the magnetic B(t) field response from the reservoir rocks, using a virtual vertical electric bipole source. The system is formed by a star electrode system 10 and 11, simulating vertical electric bipole 12, and a set of magnetic field receivers 3, distributed on the ground over the target reservoir 5.

FIG. 4 illustrates yet another embodiment of a reservoir monitoring system for measuring the magnetic B(t) field response from the reservoir rocks, using a virtual vertical electric bipole source. The system is formed by a star electrode system 10 and 11, simulating vertical electric bipole 12, and a set of magnetic field receivers 3, distributed on the ground over the target reservoir 5 and/or underground within the borehole, 4.

FIG. 5 is a flow chart illustrating a method for monitoring the subsurface reservoir using SQUID magnetic sensors according to present disclosure.

### DETAILED DESCRIPTION

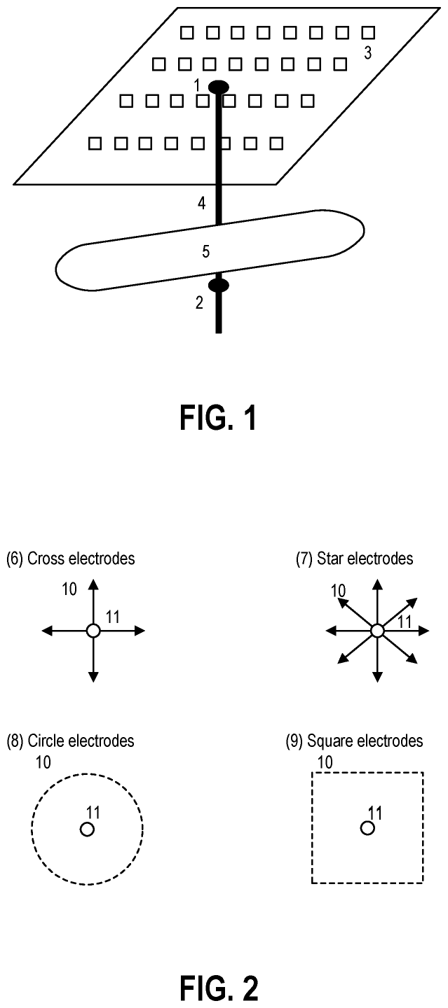

One embodiment of a method for subsurface reservoir monitoring using data acquisition system that measures magnetic time-domain responses is shown in FIG. 1, which illustrates an embodiment of a SQUID surveying system of the present invention. This system may include transmitting bipole consisting of two electrode points: one surface grounding point, the electrode 1, and electrode 2 grounded at well casing or inside the borehole, and a set of magnetic receivers, 3, distributed around the borehole.

In the embodiment shown, the magnetic field sensors 3 may record any one or all three mutually orthogonal components of the time domain magnetic field, Bx(t), By(t), Bz(t), generated in subsurface geological formations by the vertical electric bipole source formed by electrodes 1 and 2, located in the borehole 4. The volume distribution of electromagnetic parameters within the reservoir may then be derived from the recorded B-field data, using a 3D EM inversion technique as described by Zhdanov (2018). The recovered distribution of electromagnetic parameters within the reservoir layers may be used for monitoring of the movement of the fluid in the subsurface geological formations.

In accordance with embodiments of the present disclosure, to monitor, measure, and/or quantify a subsurface reservoir, a vertical bipole source may be inserted into a borehole. In some embodiments, the vertical bipole source may be inserted into a drillstring during drilling operations. In some embodiments, the vertical bipole source may be inserted into a producing wellbore. In some embodiments, the vertical bipole source may include a current generator configured to generate vertical current flow along a length of the vertical bipole. Generating the vertical current along the length may include generating the current along a vertical bipole that is tens, hundreds, or thousands of meters long. In some embodiments, the vertical bipole may include a conductive element that extends along the length of the bipole. A first electrode 1 may be located at an upper end of the vertical bipole. For example, the first electrode may be located at a surface location and grounded at the surface. In some embodiments a second electrode 2 may be located at a lower end of the vertical bipole. For example, the second electrode 2 may be a casing electrode grounded at a well casing inside the borehole. A current may be passed between the first electrode 1 and the second electrode 2 to generate a time-domain B-field (e.g., magnetic field).

In some embodiments, the vertical bipole may extend through a formation and intersect a reservoir. In some embodiments, the vertical bipole may extend through an entirety of a reservoir. In some embodiments, the vertical bipole may extend through a portion of a reservoir.

When generating the vertical current flow, the vertical bipole may generate a corresponding time-domain B-field (e.g., magnetic field). The B-field may induce an electric field in the formation surrounding the borehole. Elements of the formation and/or the reservoir may be determined based on the response by the formation and/or the reservoir, using the 3D EM inversion technique previously discussed. In some embodiments, the 3D EM inversion technique includes a regularized 3D focusing nonlinear inversion of time-domain B-field data.

To receive the time-domain B-field data, at least one magnetic receiver 3 may be located at a surface location above the reservoir 5. The magnetic receivers 3 may receive the time-domain magnetic B-field response to any fluids in the rock formation. The time-domain B-field data may include mutually orthogonal components of the time-domain magnetic field, including Bx(t) (e.g., a first horizontal component), By(t) (e.g., a second horizontal component), and Bz(t) (e.g., a vertical component). The mutually orthogonal components of the time-domain B-field may be generated in the subsurface geological formations. In some embodiments, the magnetic receiver 3 may be a SQUID receiver. In some embodiments, the magnetic receivers 3 may include a plurality of sensors that are arranged in an array. The array may be within operational proximity to a target reservoir 5. In some embodiments, operational proximity may include located vertically above. In some embodiments, operational proximity may include located anywhere the magnetic receivers 3 can receive and/or measure the time-domain B-field data.

Using the received time-domain B-field data, including its mutually orthogonal components, volume images of the EM parameters of the rock formation may be determined using a 3D EM inversion technique as applied to the time-domain B-field data, as discussed above.

The EM parameters generated may be monitored for changes. For example, the EM parameters may be monitored for a period of time. A change to the EM parameters may be identified and tracked. Any changes to the volume images of the EM parameters may then be compared to images of known geological formations. By comparing the EM parameters to known images for known geological formations, parameters, changes, and other elements of a reservoir may be identified, monitored, and tracked.

In another embodiment of a method for subsurface reservoir monitoring using data acquisition system that measures magnetic time-domain responses, the vertical electric bipole source may be virtual. For example, the virtual vertical electric bipole source can be simulated by surface electrode configurations shown in FIG. 2. This figure presents four different ground electrode configurations: (6) cross electrodes; (7) star electrodes; (8) circle electrodes; and (9) square electrodes. These configurations are listed in order of improved sensitivity to the subsurface reservoir, but also in order of more complex field logistics. For all configurations, the surface grounding points (10) represent transmitting electrodes, and the surface grounding point (11) represents a receiving electrode. In the cases of the circle and square configurations, the entire surface circle or square electrodes 10 are grounded (or, in practical applications, they are represented my multiple closely located grounded electrodes as shown by dots in FIG. 2)

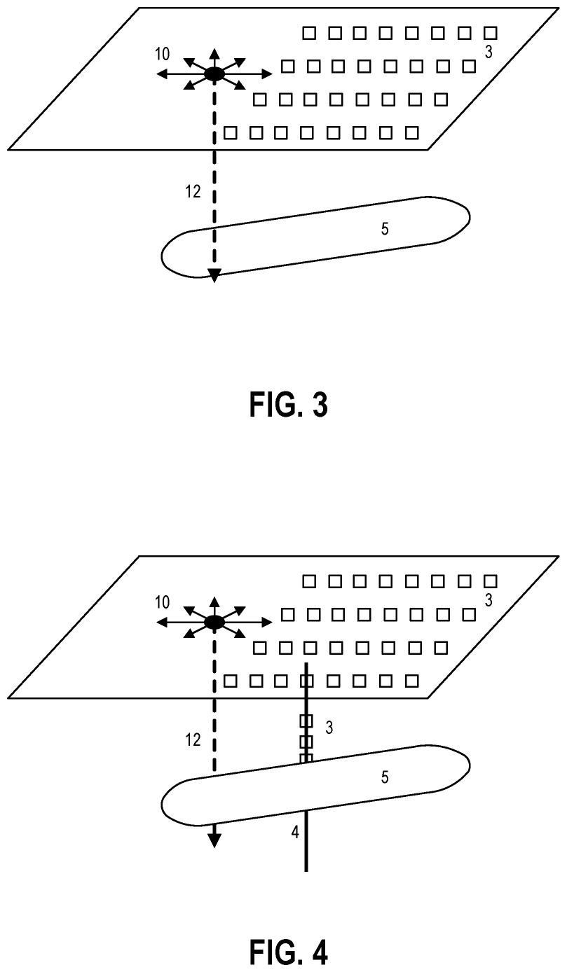

In the embodiment illustrated by FIG. 3, the magnetic field sensors 3 may record any one or all three mutually orthogonal components of the time domain magnetic field, Bx(t), By(t), Bz(t), generated in subsurface geological formations by the virtual electric bipole source 12, formed by star electrodes 10 and 11, located on the ground. Note that, the virtual vertical electric bipole source in this embodiment can also be formed by the cross, circle, or square ground electrodes, as shown in FIG. 2. The volume distribution of electromagnetic properties of the reservoir rocks and the fluids in the reservoir may then be derived from the recorded magnetic field data, using a 3D EM inversion technique as described by Zhdanov (2015, 2018). The recovered distribution of electromagnetic parameters within the reservoir layers may be used for monitoring of the movement of the fluid in the subsurface geological formations.

In yet another embodiment illustrated by FIG. 4, the magnetic field sensors 3 recording any one or all three mutually orthogonal components of the time domain magnetic field, Bx(t), By(t), Bz(t), can be located on the ground over the target reservoir 5 and/or underground in the borehole, 4. The volume distribution of electromagnetic properties of the reservoir rocks and the fluids in the reservoir may then be derived from the recorded magnetic field data, using a 3D EM inversion technique as described by Zhdanov (2015, 2018). The recovered distribution of electromagnetic parameters within the reservoir layers may be used for monitoring of the movement of the fluid in the subsurface geological formations.

More specifically, monitoring of the fluid movement in the subsurface reservoir may be implemented through a method comprising the following steps:
a) Placing an actual vertical electric bipole transmitter into the borehole, or placing a virtual vertical electric bipole source simulated by the cross, star, circular or square electrode configurations specified in FIG. 2, and an array of SQUID magnetic B-field receivers in operational association with the area of investigation;
b) acquiring time-domain magnetic B-field data using the actual or virtual vertical electric bipole source and an array of SQUID magnetic B-field receivers located on the surface and/or in the borehole;
c) determining volume images of the electromagnetic parameters of the rock formation using a 3D EM inversion technique applied to the recorded SQUID magnetic B-field data;
d) monitoring the changes of the electromagnetic parameters of the formations determined from the observed magnetic B-field data;
e) correlating the changes of said images with known geological formations for subsurface reservoir monitoring.

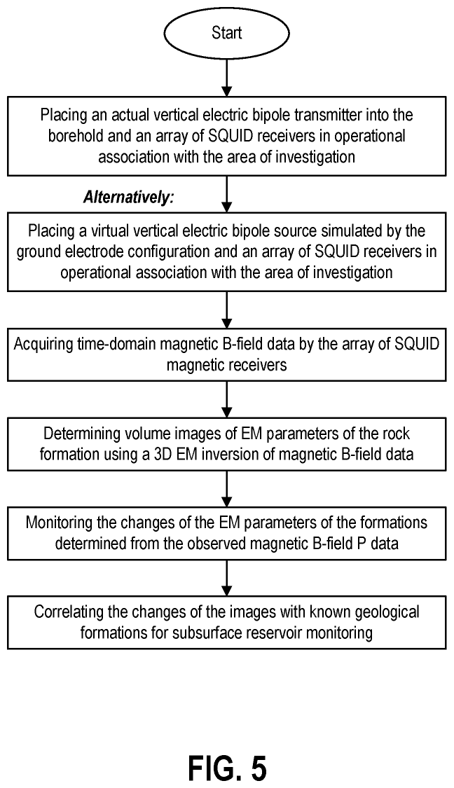

FIG. 5 shows a flow chart of the method of the current invention. According to this flow chart, an actual vertical electric bipole transmitter is placed into the borehole, or, alternatively, a virtual vertical electric bipole source simulated by the ground electrode

configurations is used to generate significant vertical current flow through the reservoir and a corresponding time-domain magnetic B-field response to the presence of fluids in reservoir rocks. The time-domain magnetic B-field data are acquired by placing the SQUID magnetic field receivers in operational association with the area of investigation. The SQUID receivers record the time domain magnetic B-field in the wide range of time interval corresponding to greater depth than by using the conventional induction coils magnetic sensors or electric field sensors.

In order to generate a volume image of EM parameters of the rock formations, those skilled in the art, may use a 3D inversion technique for interpretation of the observed time-domain magnetic B-field data in the receivers. The goal of the inversion may be to find volume images of spatial distributions of EM parameters from the observed EM data. The numerical methods of solving this problem are well developed and known for those skilled in this field (e.g., Zhdanov, 2018).

In order to produce images with the sharp contrast between the volumes occupied by the brine and the reservoir fluid, one may use focusing inversion of the recorded B-field data as described in Zhdanov (2015).

While specific embodiments and applications of the present invention have been illustrated and described, it is to be understood that the invention is not limited to the precise configuration and components disclosed herein. Various modifications, changes, and variations which will be apparent to those skilled in the art may be made in the arrangement, operation, and details of the methods and systems of the present invention disclosed herein without departing from the spirit and scope of the invention.

What is claimed is:

1. A method of subsurface reservoir monitoring, comprising:
at a vertical electric bipole source:
generating vertical current flow penetrating the reservoir and a corresponding time-domain magnetic B-field response to fluids in a rock formation;
at at least one magnetic field receiver in range of the reservoir
acquiring time-domain B-field data generated in subsurface geological formations by vertical electric bipole source by using at least one magnetic field receiver of time-domain magnetic B-field data located on a surface location or in a borehole;
determining volume images of EM parameters of the rock formation using a 3D EM inversion technique applied to the acquired time-domain B-field data monitoring a change of the EM parameters of the rock formation determined from the acquired time-domain B-field data; and
correlating the changes of the volume images with known geological formations for subsurface reservoir monitoring.

2. The method of claim 1, wherein the time-domain B-field data is acquired from at least one mutually orthogonal component of a time domain magnetic field, Bx(t), By(t), Bz(t), generated in subsurface geological formations by vertical electric bipole source by using at least one receiver of time-domain magnetic B-field data arranged on a surface location or in a borehole.

3. The method of claim 2, wherein the receiver is any one of SQUID receiver or an alternative magnetic field receiver with the magnetic field sensitivity comparable to the SQUID capabilities

4. The method of claim 1, wherein the vertical electric bipole source is arranged in a borehole.

5. The method of claim 2, wherein the vertical electric bipole source includes a surface electrode grounding point and a casing electrode grounded at a well casing.

6. The method of claim 2, wherein the vertical electric bipole source includes a surface electrode grounding point and a borehole electrode grounded inside the borehole.

7. The method of claim 1, wherein the vertical electric bipole source is a virtual vertical bipole source simulated by a ground electrode configuration.

8. The method of claim 5, wherein the virtual vertical bipole source is formed by ground cross electrode configuration.

9. The method of claim 5, wherein the virtual vertical bipole source is formed by ground star electrode configuration.

10. The method of claim 5, wherein the virtual vertical bipole source is formed by ground circle electrode configuration.

11. The method of claim 5, wherein the virtual vertical bipole source is formed by ground square electrode configuration.

12. The method of claim 5, wherein the virtual vertical bipole source is formed by ground polygon electrode configuration.

13. The method of claim 1, wherein each of the at least one magnetic field receiver includes a plurality of sensors arranged in an array in an operational proximity from a target reservoir.

14. The method of claim 1, wherein the reservoir is formed by hydrocarbon bearing rocks.

15. The method of claim 1, wherein the reservoir is formed by geothermal resources bearing formations.

16. The method of claim 1, wherein the reservoir is used for carbon dioxide (CO2) capture and storage.

17. The method of claim 1, wherein the 3D EM inversion technique is based on a regularized 3D focusing nonlinear inversion of time-domain B-field data.

18. The method of claim 1, wherein the at least one magnetic field receiver is arranged at a surface location over the reservoir.

19. The method of claim 1, wherein the at least one magnetic field receiver is arranged in a borehole intersecting the reservoir in the rock formation.

20. A method of subsurface reservoir monitoring, comprising:
receiving time-domain B-field data from at least one mutually orthogonal component of a time domain magnetic field;
determining volume images of EM parameters of a rock formation using a 3D EM inversion technique applied to the time-domain B-Field data;
monitoring a change of the EM parameters; and
correlating the change with a known geological formation.

21. The method of claim 19, wherein the time-domain B-field data is received using at least one SQUID receiver of time-domain magnetic B-field data.

22. The method of claim 19, wherein the time-domain B-field data is generated from a vertical current flow from a vertical electric bipole source.

23. A method of subsurface reservoir monitoring, comprising:
acquiring time-domain magnetic B-field data for a rock formation;
using the time-domain magnetic B-field data, generating volume images of EM parameters of the rock formation; and
correlating changes in the volume images with known geologic formations.
